(19) United States
(12) Patent Application Publication
(10) Pub. No.: US 2025/0149521 A1
(43) Pub. Date: May 8, 2025

(54) DIGITAL SIGNAL PROCESSOR TO PHOTONICS INTERFACE

(71) Applicant: MaxLinear, Inc., Carlsbad, CA (US)

(72) Inventors: Abdelkrim El Amili, San Diego, CA (US); Shahram Nikoukary, Encinitas, CA (US); Curtis Ling, Carlsbad, CA (US)

(73) Assignee: MaxLinear, Inc., Carlsbad, CA (US)

(21) Appl. No.: 18/942,319

(22) Filed: Nov. 8, 2024

Related U.S. Application Data
(60) Provisional application No. 63/597,245, filed on Nov. 8, 2023.

(51) Int. Cl. H01L 25/16; H01L 23/00; H01L 23/15; H01L 23/498

(52) U.S. Cl. CPC H01L 25/167; H01L 23/15; H01L 23/49827; H01L 24/16; H01L 24/83; H01L 24/48; H01L 2224/16225; H01L 2224/48159; H01L 2224/83203; H01L 2924/14335

(57) ABSTRACT

An electronic device includes an electrically insulating substrate, a digital signal processor, and a photonics assembly. The electrically insulating substrate includes a main body. The digital signal processor is disposed on a first surface of the electrically insulating substrate and is arranged relative to the electrically insulating substrate such that a portion of the digital signal processor extends beyond the main body of the electrically insulating substrate. The photonics assembly is disposed adjacent to the electrically insulating substrate and electrically coupled to the digital signal processor.

### CROSS REFERENCE TO RELATED APPLICATIONS

This U.S. Patent Application claims priority to U.S. Provisional Patent Application No. 63/597,245, titled “DIGITAL SIGNAL PROCESSOR TO PHOTONICS INTERFACE,” and filed on Nov. 8, 2023, the disclosure of which is hereby incorporated by reference in its entirety.

### TECHNICAL FIELD

This disclosure relates to photonics devices, and more specifically, to an interface between a digital signal processor and a photonics device.

### BACKGROUND

Unless otherwise indicated herein, the materials described herein are not prior art to the claims in the present application and are not admitted to be prior art by inclusion in this section.

Modern optical transceivers for datacenters may rely on a sophisticated combination of digital signal processors (DSPs) and photonics. Signals between the DSPs and the photonics may traverse traces in a package and/or on a printed circuit board (PCB). Due to increasing speeds of communication, it is conventional practice to design the traces to form one or more transmission line (e.g., that may be distributed) circuits that may include a standard impedance (e.g., 50 ohms). Forming the transmission line circuits using the traces may be utilized due to the trace lengths being multiples of a wavelength at the symbol rate. For example, a symbol rate of 56 gigabits per second may correspond to a wavelength of approximately 5 mm in air and/or 3 mm on a microstrip transmission line on a PCB. However, photonic devices, such as modulators and detectors, have electrical impedances which may deviate from 50 ohms. In such instances a shunt termination resistor may be added in parallel with the photonic devices to avoid reflections in the transmission line (where the reflections may have a deleterious effect on the system performance). Drawbacks of adding the shunt termination resistor may include dissipated power, reduced system gain, and/or degraded signal quality.

The subject matter claimed in the present disclosure is not limited to implementations that solve any disadvantages or that operate only in environments such as those described above. Rather, this background is only provided to illustrate one example technology area where some implementations described in the present disclosure may be practiced.

### SUMMARY

In an example embodiment, an electronic device may include an electrically insulating substrate, a digital signal processor, and a photonics assembly. The electrically insulating substrate may include a main body. The digital signal processor may be disposed on a first surface of the electrically insulating substrate and may be arranged relative to the electrically insulating substrate such that a portion of the digital signal processor may extend beyond the main body of the electrically insulating substrate. The photonics assembly may be disposed adjacent to the electrically insulating substrate and may be electrically coupled to the digital signal processor.

In another embodiment, a method may include arranging a digital signal processor on a first surface of an electrically insulating substrate such that a portion of the digital signal processor may extend beyond the main body of the electrically insulating substrate. The method may also include arranging a photonics assembly adjacent to the electrically insulating substrate and proximate to the digital signal processor. The method may further include bonding the photonics assembly to the digital signal processor such that the photonics assembly may be electrically coupled to the digital signal processor.

The objects and advantages of the embodiments will be realized and achieved at least by the elements, features, and combinations particularly pointed out in the claims. Both the foregoing general description and the following detailed description are given as examples and are explanatory and not restrictive of the invention, as claimed.

### DESCRIPTION OF DRAWINGS

Example implementations will be described and explained with additional specificity and detail using the accompanying drawings in which:

FIG. 1 illustrates a cross-sectional view of an electronic device;

FIG. 2 illustrates a perspective cross-sectional view of an electronic device;

FIGS. 3A and 3B illustrate a perspective and a cross-sectional view of a first electronic device configuration;

FIGS. 4A and 4B illustrate a perspective and a cross-sectional view of another electronic device configuration;

FIGS. 5A and 4B illustrate a perspective and a cross-sectional view of another electronic device configuration; and

FIG. 6 illustrates a flowchart of an example method of an interface between a digital signal processor and a photonics assembly.

### DETAILED DESCRIPTION

Some present interfaces between a digital signal processor (DSP) and a photonics assembly include transmission lines between the DSP and the photonics assembly to electrically couple the devices together. The transmission lines may include electrically conductive traces or micro strips arranged across a surface of a printed circuit board (PCB). In some instances, the length of the transmission lines may be tuned to be a multiple of a wavelength of a symbol rate output by the DSP. Such configurations may result in long transmission lines and/or a high impedance (due to the nature of the transmission lines). Many transmission lines include a default impedance (e.g., a fixed 50 ohm impedance), which may be difficult to match to a photonic device in the photonics assembly. Due to the impedance, a shunt termination resistor may be included to reduce reflections in the transmissions using the transmission line. The shunt resistor may introduce power dissipation, a reduction in system gain, and/or a degradation of signal quality.

Aspects of the present disclosure address these and other limitations by arranging components of an electronic device to be substantially closer to one another such that a need for a transmission line similar to previous approaches may be unnecessary. Alternatively, or additionally, the shunt resistor that was previously included to reduce reflections (and introduce system inefficiencies) may also be removed. As described herein, a DSP and a photonics assembly may be disposed near each other which may substantially reduce transmission losses, cross-talk between transmissions, and remove at least some of the inefficiencies present in traditional approaches (e.g., by removing the shunt termination resistor).

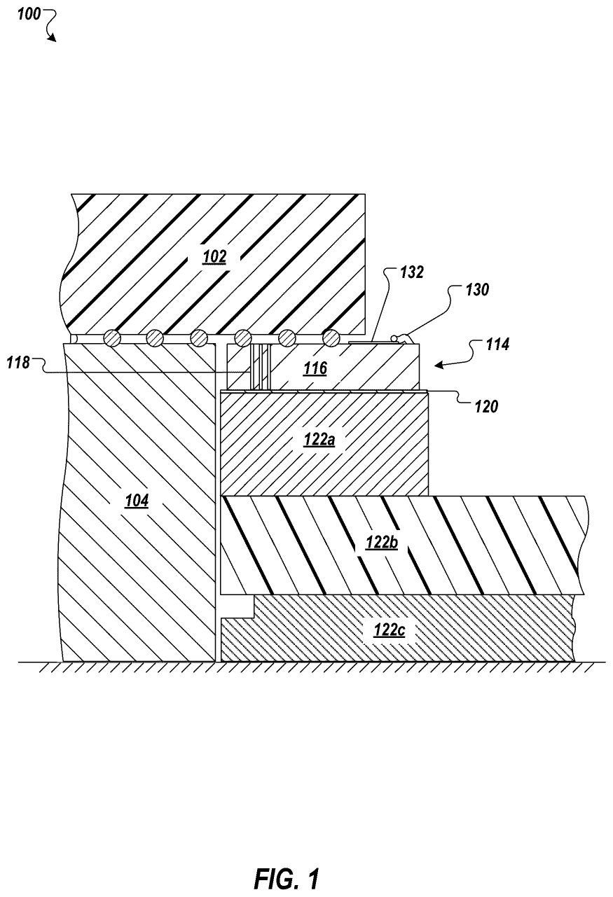

FIG. 1 illustrates a cross-sectional view of an electronic device 100, in accordance with at least one embodiment of the present disclosure. The electronic device 100 may include a digital signal processor (DSP) 102, a printed circuit board (PCB) 104, a photonics assembly 114, an interposer 116, multiple vias 118, a submount 120, a first support structure 122a, a second support structure 122b, a third support structure 122c, referred to collectively as support structures 122, a wire bond 130, and an electrical trace 132.

As illustrated in FIG. 1, the DSP 102 is mounted to a first side of the PCB 104. The DSP 102 may be mounted to a main body portion of the PCB 104 and a portion of the DSP 102 may extend beyond the main body of the PCB 104. In some instances, the PCB 104 may be formed from FR4 and/or may include multiple surface traces and/or the first vias 112 that may be operable to facilitate electrical communications between the DSP 102 and one or more other electrical components mounted to the PCB 104, such as the photonics assembly 114. In some instances, the PCB 104 may include core having a different material than other portions of the PCB 104. For example, in some instances, the PCB 104 may include a glass core.

In some instances, the DSP 102 may be electrically coupled to the photonics assembly 114 such that communications may occur between the DSP 102 and the photonics assembly 114. In some instances, the photonics assembly 114 may include the interposer 116 that may include electrically conductive pathways to facilitate communications from the DSP 102 to one or more photonics devices of the photonics assembly 114. For example, the interposer 116 may include the vias 118 that may be operable to route signals to the submount 120 of the photonics assembly 114.

In some instances, the connection between the DSP 102 and the photonics assembly 114 may be based on materials that are used in the photonics assembly 114. For example, in instances in which the photonics assembly 114 includes a silicon photonics device, the photonics assembly 114 may be bonded directly to the DSP 102 (e.g., the interposer 116 may not be included in the electronic device 100). In another example, in instances in which the photonics assembly 114 is a thin-film lithium niobate photonics device, then the photonics assembly 114 may be coupled with the interposer 116 and further bonded to the DSP 102. Other materials than those listed may be used, and some may facilitate bonding directly to the DSP 102 (e.g., similar to the silicon photonics device) while others may be bonded with the DSP 102 with the use of the interposer 116 (e.g., similar to the thin-film lithium niobate photonics device).

In these and other embodiments, thermocompression bonding may be utilized to couple the photonics assembly 114 to the DSP 102. Thermocompression bonding may be utilized in either of the example bonding configurations described herein, including instances in which the interposer 116 is present and/or instances in which the interposer 116 is not included in the electronic device 100. In instances in which thermocompression bonding is utilized, no solder may be included on the portion of the DSP 102 that extends beyond the main body of the PCB 104, and copper pillars on such portion of the DSP 102 may remain, such as for facilitating communications to the photonics assembly 114. Alternatively, or additionally, the photonics assembly 114 may be coupled to the DSP 102 using surface mount technology techniques, such as a ball grid array process.

In some instances, the photonics assembly 114 may be supported in place by the support structures 122. While the support structures 122 include multiple separate components, it should be appreciated that as few as a single support structure may be used to support the photonics assembly 114. In this particular embodiment, the support structures 122 may contribute to preventing an application of an undesired forces on the photonics assembly 114 that could cause structural damage to the photonics assembly 114. In some instances, the support structures 122 may be formed from electrically insulating materials, such as epoxy coated fiberglass.

As illustrated in FIG. 1, the photonics package 124 may be disposed on the submount 120 and/or may be disposed adjacent to the interposer 116. Such an arrangement may contribute to minimizing a length of electrical pathways between the interposer 116 and the photonics package 124. The interposer 116 may include the wire bond 130 that may extend between an electro-absorption modulator associated with the photonics assembly 114 and the electrical trace 132. The wire bond 130 may be short (e.g., in terms of a physical length). For example, the wire bond 130 may include a length that may be less than 150 microns. The electrical trace 132 may be operable to route signals between the wire bond 130 and the vias 118. As illustrated in FIG. 1, the photonics assembly 114 is a single photonics assembly. It should be appreciated that the electronic device 100 may be operable to incorporate multiple photonics assemblies, such as by extending a width of the DSP 102. Such an arrangement could allow for the incorporation of the described embodiments into an optical transceiver with multiple ports.

Modifications, additions, or omissions may be made to the electronic device 100 without departing from the scope of the present disclosure. For example, the designations of different elements in the manner described is meant to help explain concepts described herein and is not limiting. Further, the electronic device 100 may include any number of other elements or may be implemented within other systems or contexts than those described. For example, any of the components of FIG. 1 may be divided into additional or combined into fewer components.

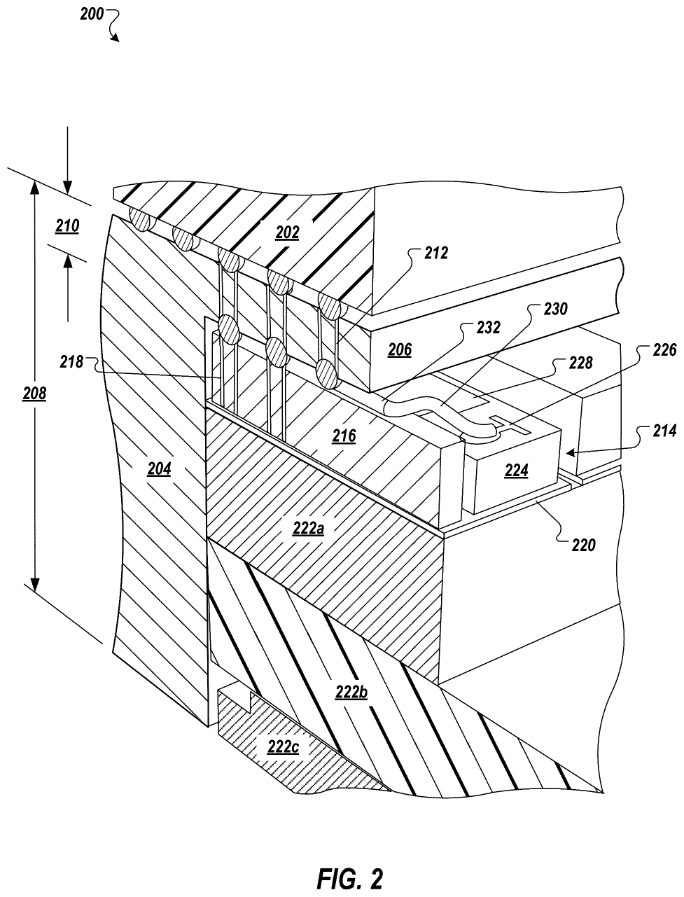

FIG. 2 illustrates a perspective cross-sectional view of an electronic device 200,

in accordance with at least one embodiment of the present disclosure. The electronic device 200 may include a digital signal processor (DSP) 202, a printed circuit board (PCB) 204, a shelf portion 206, first vias 212, a photonics assembly 214, an interposer 216, second vias 218, a submount 220, a first support structure 222a, a second support structure 222b, a third support structure 222c, referred to collectively as support structures 222, a photonics package 224, an electro-absorption modulator 226, a laser diode 228, a wire bond 230, and an electrical trace 232.

As illustrated in FIG. 2, the DSP 202 is mounted to first side of the PCB 204. In some instances, the PCB 204 may be formed from FR4 and/or may include multiple surface traces and/or the first vias 212 that may be operable to facilitate electrical communications between the DSP 202 and one or more other electrical components mounted to the PCB 204, such as the photonics assembly 214. The DSP 202 may be mounted to the first side of the PCB 204 of using surface mount technology techniques. As illustrated in FIG. 2, the DSP 202 is mounted to the PCB 204 using a ball grid array process. It should be appreciated that other attachment mechanisms are also possible and considered to be within the scope of the described embodiments.

In some instances, terminals of the DSP 202, that may be designed to interact with the photonics assembly 214, may be located on a far side of the DSP 202 as depicted. The location of the terminals of the DSP 202 may facilitate control signals being generated by the DSP 202 to be routed directly through the shelf portion 206 of the PCB 204. In some instances, a main body of the PCB 204 may include a first thickness 208 and the shelf portion 206 of the PCB 204 may include a second thickness 210. In some instances, the second thickness 210 may be substantially thinner than the first thickness 208 of the PCB 204. In some instances, the second thickness 210 (e.g., the thickness of the shelf portion 206) may be between 50 and 200 microns, while the first thickness 208 (e.g., the thickness of the main body of the PCB 204) may be between 1 mm and 6 mm.

Such an arrangement may support a disposition of the photonics assembly 214 to be beneath at least a portion of the DSP 202. As such and in conjunction with the thinness of the second thickness 210 of the shelf portion 206, the length of electrical pathways between the DSP 202 and the photonics assembly 214 may be substantially shorter than electrical pathways utilized in some current techniques of communications between a DSP and a photonics device.

In some instances, the photonics assembly 214 may include the interposer 216, and the interposer 216 may include electrically conductive pathways that helps deliver signals routed through the first vias 212 that extend through the shelf portion 206 to one or more photonics devices of the photonics assembly 214. For example, the interposer 216 may include the second vias 218 that may be operable to route signals to the submount 220 of the photonics assembly 214.

In some instances, the photonics assembly 214 may be supported in place by the support structures 222. While the support structures 222 include multiple separate components, it should be appreciated that as few as a single support structure may be used to support the photonics assembly 214. In this particular embodiment, the support structures 222 may contribute to preventing an application of an undesired forces on the shelf portion 206 that could cause structural damage to shelf portion 206 and/or the photonics assembly 214. In some instances, the support structures 222 may be formed from electrically insulating materials, such as epoxy coated fiberglass.

As illustrated in FIG. 2, the photonics package 224 may be disposed on the submount 220 and/or may be disposed adjacent to the interposer 216. Such an arrangement may contribute to minimizing a length of electrical pathways between the interposer 216 and the photonics package 224. Further illustrated is how the photonics package 224 may take the form of an electro-absorption modulated laser (EML) device that may include the electro-absorption modulator 226 and/or the laser diode 228. The electro-absorption modulator 226 and the laser diode 228 may be operable to convert electrical signals received from the DSP 202 to optical signals. As illustrated, the photonics package 224 is an EML device. It should be appreciated that the photonics package 224 can take other forms of photonics devices, such as a Mach-Zehnder modulator.

The interposer 216 may include the wire bond 230 that may extend between the electro-absorption modulator 226 and the electrical trace 232. The wire bond 230 may be short (e.g., in terms of a physical length). For example, the wire bond 230 may include a length that may be less than 150 microns. The electrical trace 232 may be operable to route signals between the wire bond 230 and the first vias 212. As illustrated in FIG. 2, the photonics assembly 214 is a single photonics assembly. It should be appreciated that the electronic device 200 may be operable to incorporate multiple photonics assemblies, such as by extending a width of the shelf portion 206 and/or a width of the DSP 202. Such an arrangement could allow for the incorporation of the described embodiments into an optical transceiver with multiple ports.

Modifications, additions, or omissions may be made to the electronic device 200 without departing from the scope of the present disclosure. For example, the designations of different elements in the manner described is meant to help explain concepts described herein and is not limiting. Further, the electronic device 200 may include any number of other elements or may be implemented within other systems or contexts than those described. For example, any of the components of FIG. 2 may be divided into additional or combined into fewer components.

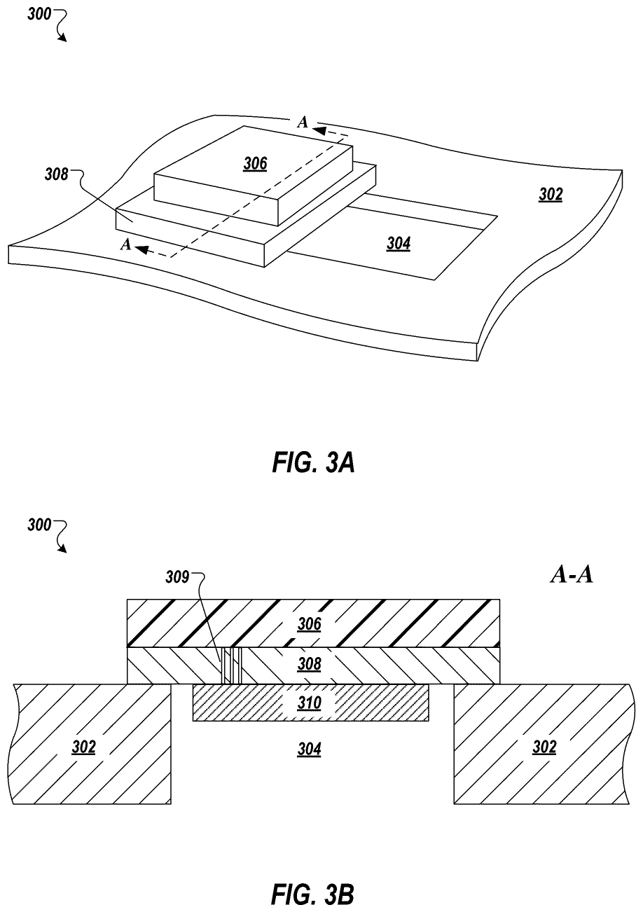

FIGS. 3A and 3B illustrate a perspective view and a cross-sectional view of a first electronic device configuration 300, each in accordance with at least one embodiment of the present disclosure. FIG. 3A illustrates the first electronic device configuration 300 in a configuration in which a printed circuit board (PCB) 302 includes a cutout 304. A digital signal processor (DSP) 306 may be electrically and/or mechanically coupled to an interposer 308, which may extend at least partially over the cutout 304 of the PCB 302. The interposer 308 may be electrically coupled to a peripheral region of the PCB 302 arranged along the cutout 304 such that the DSP 306 may be capable of communication with other components mounted atop the PCB 302. In some instances, the interposer 308 may have a thickness between approximately 50 and 200 microns and may include one or more vias operable to electrically couple the DSP 306 with a photonics assembly (not illustrated). The photonics assembly may be coupled to a surface of the interposer 308 opposite the DSP 306 (e.g., a downward facing surface as illustrated in FIG. 3A). In some instances, the photonics assembly may extend into the cutout 304. The peripheral region of the PCB 302 may contribute to providing structural support for the interposer 308 and/or may help prevent unwanted bending or damage to the interposer 308. Alternatively, or additionally, similar structural benefits may be extended to the photonics device coupled to the interposer 308.

FIG. 3B illustrates a cross-sectional side view of the electronic device configuration 300 in accordance with section line A-A included in FIG. 3A. In particular, FIG. 3B illustrates a photonics assembly 310 extending into the cutout 304. FIG. 3B also shows multiple vias 309 extending through the interposer 308. The multiple vias 309 may create low impedance, electrically conductive pathways operable to electrically couple the DSP 306 to the photonics assembly 310. In some instances, a portion of the cutout 304 may be left uncovered to allow for one or more fiber optic cables to be routed to the photonics assembly 310.

Modifications, additions, or omissions may be made to the first electronic device configuration 300 without departing from the scope of the present disclosure. For example, the designations of different elements in the manner described is meant to help explain concepts described herein and is not limiting. Further, the first electronic device configuration 300 may include any number of other elements or may be implemented within other systems or contexts than those described. For example, any of the components of FIGS. 3A and 3B may be divided into additional or combined into fewer components.

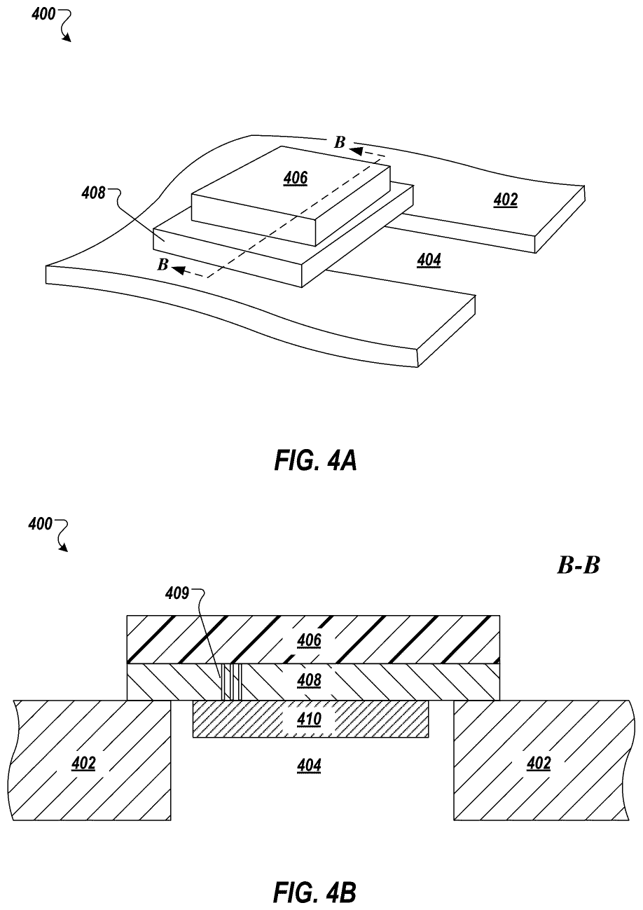

FIGS. 4A and 4B illustrate a perspective view and a cross-sectional view of a second electronic device configuration 400, each in accordance with at least one embodiment of the present disclosure. FIG. 4A illustrates the second electronic device configuration 400 in a configuration in which a printed circuit board (PCB) 402 includes a notch 404 instead of a cutout (e.g., the cutout 304 in FIG. 3A). As with the first electronic device configuration 300 illustrated in FIG. 3A, a digital signal processor (DSP) 406 may be mounted to an interposer 408, where the interposer 408 may extend over at least a portion of the notch 404. In such an arrangement, a photonics assembly may be coupled to the interposer 408, such that the photonics assembly may extend into the notch 404 (e.g., similarly to the photonics assembly extending into the cutout 304 as described relative to FIG. 3A).

FIG. 4B illustrates a cross-sectional side view of the second electronic device configuration 400 in accordance with section line B-B included in FIG. 4A. As with the first electronic device configuration 300 of FIGS. 3A and 3B, the second electronic device configuration 400 may include a photonic assembly 410 that may be coupled to the interposer 408 and the photonic assembly 410 may extend into the notch 404. The interposer 408 may include multiple vias 409 that may be operable to electrically couple the DSP 406 to the photonics assembly 410.

Modifications, additions, or omissions may be made to the second electronic device configuration 400 without departing from the scope of the present disclosure. For example, the designations of different elements in the manner described is meant to help explain concepts described herein and is not limiting. Further, the second electronic device configuration 400 may include any number of other elements or may be implemented within other systems or contexts than those described. For example, any of the components of FIGS. 4A and 4B may be divided into additional or combined into fewer components.

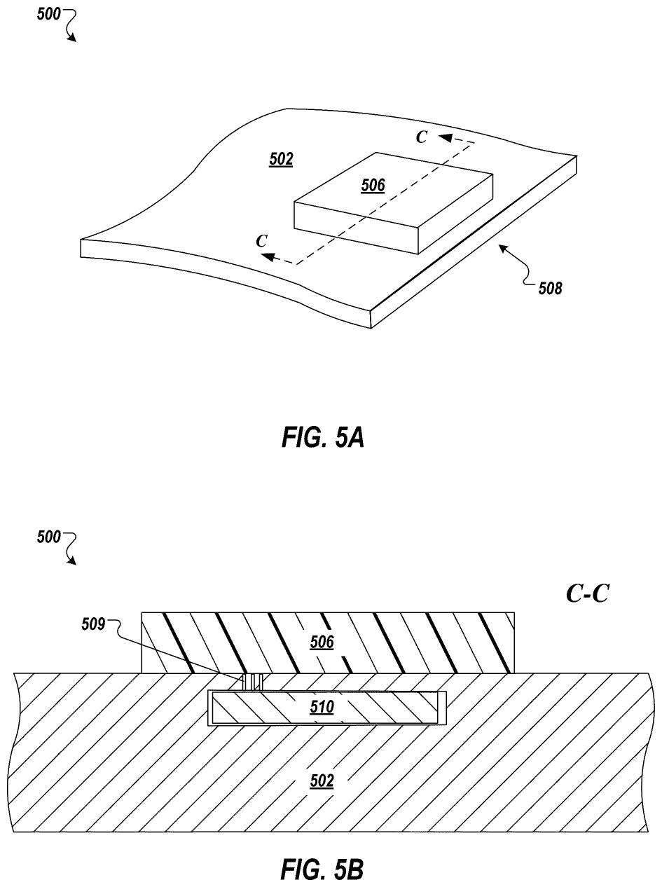

FIGS. 5A and 5B illustrate a perspective view and a cross-sectional view of a third electronic device configuration 500, each in accordance with at least one embodiment of the present disclosure. FIG. 5A illustrates the third electronic device configuration 500 in a configuration in which a photonics assembly 510 is encapsulated within a printed circuit board (PCB) 502 beneath a digital signal processor (DSP) 506. The DSP 506 may be positioned proximate to an edge 508 of the PCB 502. In some instances, multiple vias 509 may facilitate a low impedance, electrical connection between the DSP 506 and the photonics assembly 510. In some instances, the multiple vias 509 may each have a length of approximately between 50 and 200 microns. In some instances, the positioning of the photonics assembly 510 near the edge 508 of the PCB 502 may facilitate the PCB 502 accommodating passage of fiber optic cables into the photonics assembly 510, such as through one or more openings in the PCB 502. In these and other embodiments, one end of the photonics assembly 510 may be exposed to or protrude from the edge 508 of the PCB 502 to ease the attachment of fiber optic cables to photonics assembly 510.

FIG. 5B illustrates a cross-sectional side view of the third electronic device configuration 500 in accordance with section line C-C included in FIG. 5A. The third electronic device configuration 500 may include a photonic assembly 510 that may be coupled to the PCB 502 and the photonic assembly 510 may be encapsulated within a portion of the PCB 502. Alternatively, or additionally, the PCB 502 may include the multiple vias 509 that may be operable to electrically couple the DSP 506 to the photonics assembly 510.

Modifications, additions, or omissions may be made to the third electronic device configuration 500 without departing from the scope of the present disclosure. For example, the designations of different elements in the manner described is meant to help explain concepts described herein and is not limiting. Further, the third electronic device configuration 500 may include any number of other elements or may be implemented within other systems or contexts than those described. For example, any of the components of FIGS. 5A and 5B may be divided into additional or combined into fewer components.

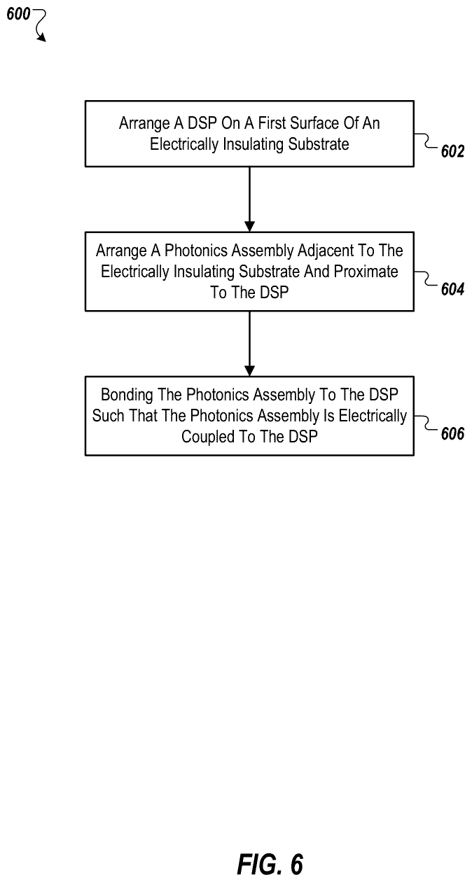

FIG. 6 illustrates a flowchart of an example method 600 of an interface between a digital signal processor (DSP) and a photonics assembly, in accordance with at least one embodiment of the present disclosure. The method 600 may be performed by processing logic that may include hardware (circuitry, dedicated logic, etc.), software (such as is run on a general purpose computer system or a dedicated machine), or a combination of both, which processing logic may be included in any computer system or device.

For simplicity of explanation, the method 600 described herein is depicted and described as a series of acts. However, acts in accordance with this disclosure may occur in various orders and/or concurrently, and with other acts not presented and described herein. Further, not all illustrated acts may be used to implement the methods in accordance with the disclosed subject matter. In addition, those skilled in the art will understand and appreciate that the methods may alternatively be represented as a series of interrelated states via a state diagram or events. Additionally, the methods disclosed in this specification may be capable of being stored on an article of manufacture, such as a non-transitory computer-readable medium, to facilitate transporting and transferring such methods to computing devices. The term article of manufacture, as used herein, is intended to encompass a computer program accessible from any computer-readable device or storage media. Although illustrated as discrete blocks, various blocks may be divided into additional blocks, combined into fewer blocks, or eliminated, depending on the desired implementation.

At block 602, a DSP on a first surface of an electrically insulating substrate may be arranged such that a portion of the DSP may extend beyond the main body of the electrically insulating substrate. In some instances, the electrically insulating substrate may be printed circuit board and may include a glass core.

In some instances, the electrically insulating substrate may include a shelf portion that may extend from the main body. The shelf portion may include multiple vias disposed therein, where the multiple vias may extend from a first side of the shelf portion to a second side of the shelf portion. The portion of the DSP may be disposed on the first side of the shelf portion and the photonics assembly may be disposed on the second side of the shelf portion. The photonics assembly may be electrically coupled to the DSP using the multiple vias.

At block 604, a photonics assembly may be arranged adjacent to the electrically insulating substrate and may be proximate to the DSP. In some instances, an interposer may be disposed between the shelf portion and the photonics assembly. Alternatively, or additionally, the interposer may be disposed between the DSP and the photonics assembly.

The interposer may include electrically conductive pathways which may facilitate communication between the DSP and the photonics assembly. In instances in which the shelf portion is included, the interposer may include electrically conductive pathways aligned with the multiple vias in the shelf portion to facilitate communication between the DSP and the photonics assembly.

At block 606, the photonics assembly may be bonded to the DSP such that the photonics assembly may be electrically coupled to the DSP. In some instances, the bonding of the photonics assembly to the digital signal processor may include thermocompression bonding.

Modifications, additions, or omissions may be made to the method 600 without departing from the scope of the present disclosure. For example, in some instances, an optical signal may be output from an electro-absorption modulated laser that may be associated with the first diode and the second diode. The optical signal may be based at least on the photocurrent. In another example, a reflection of the optical signal may be obtained and an optical alignment of the electro-absorption modulated laser may be performed using the optical signal and/or the reflected optical signal.

In another example, the designations of different elements in the manner described is meant to help explain concepts described herein and is not limiting. Further, the method 600 may include any number of other elements or may be implemented within other systems or contexts than those described.

Terms used in the present disclosure and especially in the appended claims (e.g., bodies of the appended claims) are generally intended as “open terms” (e.g., the term “including” should be interpreted as “including, but not limited to.”).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to implementations containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is expressly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” or “one or more of A, B, and C, etc.” is used, in general such a construction is intended to include A alone, B alone, C alone, A and B together, A and C together, B and C together, or A, B, and C together, etc.

Further, any disjunctive word or phrase preceding two or more alternative terms, whether in the description, claims, or drawings, should be understood to contemplate the possibilities of including one of the terms, either of the terms, or both of the terms. For example, the phrase “A or B” should be understood to include the possibilities of “A” or “B” or “A and B.”

All examples and conditional language recited in the present disclosure are intended for pedagogical objects to aid the reader in understanding the present disclosure and the concepts contributed by the inventor to furthering the art, and are to be construed as being without limitation to such specifically recited examples and conditions. Although implementations of the present disclosure have been described in detail, various changes, substitutions, and alterations could be made hereto without departing from the spirit and scope of the present disclosure.

What is claimed is:

1. An electronic device, comprising:
an electrically insulating substrate having a main body;
a digital signal processor disposed on a first surface of the electrically insulating substrate and arranged relative to the electrically insulating substrate such that a portion of the digital signal processor extends beyond the main body of the electrically insulating substrate; and
a photonics assembly disposed adjacent to the electrically insulating substrate and electrically coupled to the digital signal processor.

2. The electronic device of claim 1, wherein the electrically insulating substrate further comprises:
a shelf portion extended from the main body of the electrically insulating substrate; and
a plurality of vias disposed in the shelf portion extending from a first side of the shelf portion to a second side of the shelf portion.

3. The electronic device of claim 2, wherein:
the portion of the digital signal processor is disposed on the first side of the shelf portion;
the photonics assembly is disposed on the second side of the shelf portion; and
the photonics assembly is electrically coupled to the digital signal processor using the plurality of vias disposed in the shelf portion.

4. The electronic device of claim 2, wherein the main body has a first thickness and the shelf portion has a second thickness that is less than the first thickness.

5. The electronic device of claim 4, wherein the second thickness is less than 100 microns.

6. The electronic device of claim 2, wherein:
an interposer is disposed between the shelf portion and the photonics assembly; and
the interposer comprises electrically conductive pathways aligned with the plurality of vias in the shelf portion to facilitate communication between the digital signal processor and the photonics assembly.

7. The electronic device of claim 2, wherein the digital signal processor is coupled to the shelf portion using a ball grid array technique and the photonics assembly is coupled to the shelf portion using the ball grid array technique.

8. The electronic device of claim 2, wherein the photonics assembly comprises a thin-film lithium niobate photonics device.

9. The electronic device of claim 1, wherein the photonics assembly is disposed adjacent to the portion of the digital signal processor that extends beyond the main body.

10. The electronic device of claim 1, wherein the electrically insulating substrate is a printed circuit board and the printed circuit board includes a glass core.

11. The electronic device of claim 1, wherein the photonics assembly comprises an electro-absorption modulated laser.

12. The electronic device of claim 1, wherein an interposer is disposed between the digital signal processor and the photonics assembly.

13. The electronic device of claim 1, wherein the photonics assembly is coupled to the digital signal processor using thermocompression bonding.

14. The electronic device of claim 1, wherein the photonics assembly comprises a silicon photonics device.

15. A method, comprising:
arranging a digital signal processor on a first surface of an electrically insulating substrate such that a portion of the digital signal processor extends beyond a main body of the electrically insulating substrate;
arranging a photonics assembly adjacent to the electrically insulating substrate and proximate to the digital signal processor; and
bonding the photonics assembly to the digital signal processor such that the photonics assembly is electrically coupled to the digital signal processor.

16. The method of claim 15, wherein:
the electrically insulating substrate comprises a shelf portion extended from the main body;
a plurality of vias are disposed in the shelf portion extending from a first side of the shelf portion to a second side of the shelf portion;
the portion of the digital signal processor is disposed on the first side of the shelf portion; and
the photonics assembly is disposed on the second side of the shelf portion and is electrically coupled to the digital signal processor using the plurality of vias.

17. The method of claim 16, wherein:
an interposer is disposed between the shelf portion and the photonics assembly; and
the interposer comprises electrically conductive pathways aligned with the plurality of vias in the shelf portion to facilitate communication between the digital signal processor and the photonics assembly.

18. The method of claim 15, wherein the electrically insulating substrate is a printed circuit board and the printed circuit board includes a glass core.

19. The method of claim 15, wherein an interposer is disposed between the digital signal processor and the photonics assembly.

20. The method of claim 15, wherein the bonding of the photonics assembly to the digital signal processor comprises thermocompression bonding.
